(19) United States
(12) Patent Application Publication
(10) Pub. No.: US 2021/0391511 A1
(43) Pub. Date: Dec. 16, 2021

(54) LIGHT SOURCE MODULE

(71) Applicant: Qisda Corporation, Taoyuan City (TW)

(72) Inventors: Jyun-Sheng SYU, Taoyuan City (TW); Meng-Wei LIN, Taoyuan City (TW)

(73) Assignee: Qisda Corporation, Taoyuan City (TW)

(21) Appl. No.: 17/345,071

(22) Filed: Jun. 11, 2021

(30) Foreign Application Priority Data
Jun. 12, 2020 (TW) 109119779

(51) Int. Cl. H01L 33/50; H01L 25/13; H01L 33/48; H01L 33/60

(52) U.S. Cl. CPC H01L 33/507; H01L 33/60; H01L 33/483; H01L 25/13

(57) ABSTRACT

A light source module includes a circuit substrate, a plurality of light emitting units, a plurality of microstructures and a wavelength converting layer. The circuit substrate includes a first surface and has a recessed portion recessed inwardly from the first surface. The circuit substrate forms a bottom and a sidewall in the recessed portion. The light emitting units are disposed on the bottom and located in the recessed portion. The microstructures are disposed on at least one of the bottom and the sidewall. The wavelength converting unit covers the light emitting units, and fills the recessed portion.

This application claims the benefit of Taiwan application Serial No. 109119779, filed Jun. 12, 2020, the subject matter of which is incorporated by reference herein in its entirety.

### TECHNICAL FIELD

The invention relates in general to a light source module, and more particularly to a light source module with reduced thickness.

### BACKGROUND

The existing display devices gradually develop into thinness devices. Edge lighted backlight module is adopted into some of the display devices, and the light source module is set inside the bezel of the display device to reduce the size of the display device in the thickness direction.

However, with the current trend of the display device with narrow bezel, the thickness of the light source module itself must also be further reduced.

### SUMMARY

The present invention is directed to a light source module that can reduce the thickness of the light source module while maintaining a certain mixing distance.

According to one embodiment, a light module is provided. The light source module includes a circuit substrate, a plurality of light emitting units, a plurality of microstructures and a wavelength converting layer. The circuit substrate includes a first surface and has a recessed portion recessed inwardly from the first surface. The circuit substrate forms a bottom and a sidewall in the recessed portion. The light emitting units are disposed on the bottom and located in the recessed portion. The microstructures are disposed on at least one of the bottom and the sidewall. The wavelength converting unit covers the light emitting units, and fills the recessed portion.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a display device according to one embodiment of the present invention.

FIG. 2 is a three-dimensional view of the light source module according to one embodiment of the present invention.

FIG. 3 is a three-dimensional view of a light source module according to another embodiment of the present invention.

FIG. 4 is a cross-sectional view of the light source module along the cutting line 4-4′ in FIG. 2.

FIG. 5 is a cross-sectional view of a light source module according to still another embodiment of the present invention.

FIG. 6 is a three-dimensional view of a light source module according to a further embodiment of the present invention.

FIG. 7 is a cross-sectional view of the light source module along the cutting line 7-7′ in FIG. 6.

FIG. 8 is a cross-sectional view of a light source module according to other embodiment of the present invention.

### DETAILED DESCRIPTION

Each embodiment of the present invention will be described in detail hereinafter, and illustrated with the accompanying drawings. In addition to these detailed descriptions, the present invention may be broadly practiced in other embodiments, and any substitution, modification, or equivalent variation of any of the described embodiments is included within the scope of the present invention, subject to the scope of the claims thereafter. In the description of the specification, many specific details are provided in order to give the reader a more complete understanding of the present invention; however, the present invention may be practiced with the omission of some or all of these specific details. In addition, well-known steps or elements are not described in detail to avoid unnecessary limitations of the present invention. Identical or similar elements in the drawings will be indicated by identical or similar reference numerals. In particular, the drawings are only for illustrative purposes and do not represent the actual size or number of elements, unless they are otherwise indicated.

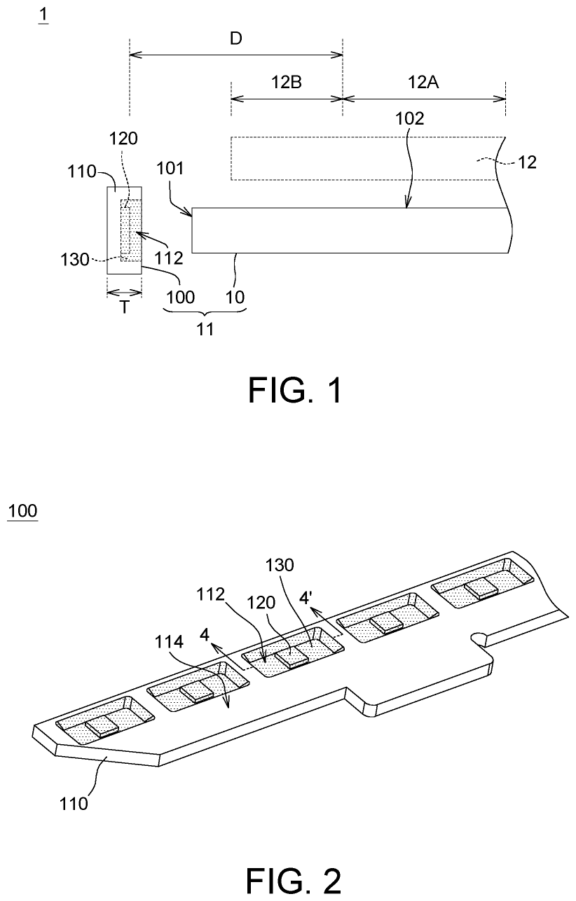

Referring to FIG. 1, a schematic diagram of a display device 1 according to one embodiment of the present invention is shown. The display device 1 includes a backlight module 11 and a display panel 12. The backlight module 11 is disposed on one side of the display panel 12 to provide light to the display panel 12 for image display.

The display panel 12 has an exposed area 12A and a non-exposed area 12B, and the exposed area 12A and the non-exposed area 12B are connected to each other. The exposed area 12A may include an active area of the display panel 12, and the non-exposed area 12B may include an outer lead area of the display panel 12, but the present invention is not limited thereto. In another embodiment, the exposed area 12A includes an active area and a visible area. In other words, the exposed area 12A is the uncovered portion of the bezel (not shown) of the display device 1, and is thus visible to the outside. The non-exposed area 12B is the portion of the display device 1 that is hidden by the bezel of the display device 1 and is thus not visible to the outside.

The backlight module 11 includes a light source module 100 and a light guide plate 10. The light guide plate 10 has a light incident surface 101 and a light emitting surface 102. The light emitting surface 102 faces the display panel 12, and the light incident surface 101 is located between the light emitting surface 102 and the bottom surface (not designated) of the light guide plate 10. In the present embodiment, the light source module 100 is laterally oriented, and the light source module 100 is located on one side of the light incident surface 101. The light provided by the light source module 100 is directed into the light guide plate 10, and through the guidance of the structure of the light guide plate 10, a uniformly distributed surface light source may be produced on the light emitting surface 102.

The light source module 100 includes a circuit substrate 110, a plurality of light emitting units 120, and a wavelength converting layer 130. The circuit substrate 110 may be, but not limited to, a printed circuit board, a metal core printed circuit board (MCPCB), a ceramic substrate, a direct bonding copper (DBC) ceramic substrate, etc.

The light emitting unit 120 may be a light emitting diode, such as an organic light emitting diode, a micro light emitting diode, a quantum dot light emitting diode, and so on. The light emitting units 120 are disposed on the circuit substrate 110 by means of surface mount technology (SMT), but the invention is not limited thereto. In some embodiments, the light emitting unit 120 may be a single-sided light emitting unit; in other embodiments, the light emitting unit 120 may be a five-sided light emitting unit to further improve the efficiency of optical coupling.

The wavelength converting layer 130 covers the light emitting units 120 and fills the recessed portion 112, capable of converting monochromatic light into light with different wavelengths for the process of mixing light. The wavelength converting layer 130 may include a fluorophore material such as Yttrium Aluminum Garnet (YAG) fluorophore, potassium fluoride silicon (KSF) fluorophore, etc. In another embodiment, the wavelength converting layer 130 may also include a quantum dot material, or other suitable wavelength converting material or the combination thereof.

In particular, the circuit substrate 110 also has a recessed portion 112, and the light emitting units 120 are disposed in the recessed portion 112. In the present invention, the recessed portion 112 may further extend the light mixing distance D between the light emitting units 120 and the exposed area 12A.

In detail, the light emitting units are generally disposed on the surface of the circuit substrate. Generally speaking, the light source module is expected to be positioned closer to the light guide plate to meet the trend of narrow bezel. However, if the position of the light source module is too close to the light guide plate, the light emitting units are too close to the light incident surface of the light guide plate, which may result in insufficient mixing distance and affect the light mixing effect. In the present invention, providing a recessed portion 112 in the circuit substrate 110 may not only maintain a certain mixing distance D, but also further reduce the overall thickness T of the light source module 100.

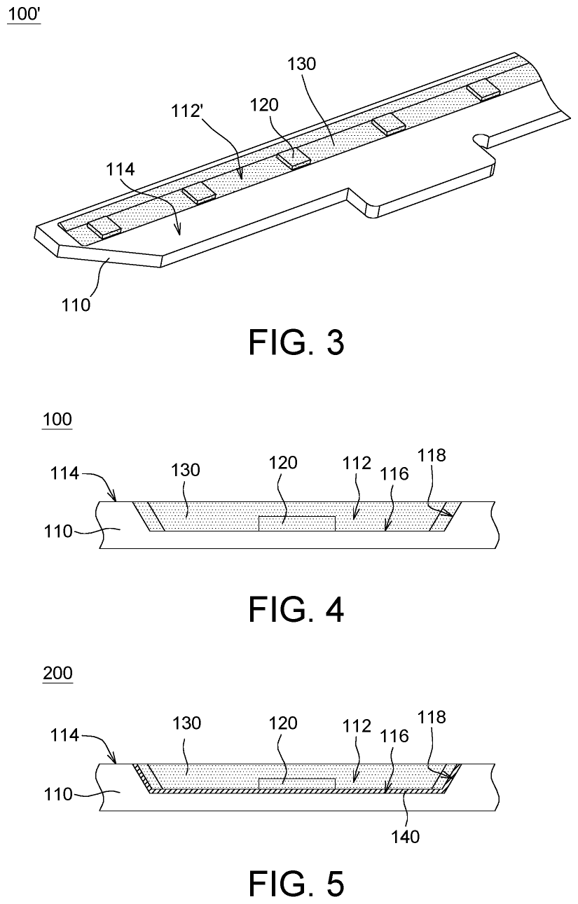

FIG. 2 is a three-dimensional view of the light source module 100 according to one embodiment of the present invention. FIG. 3 is a three-dimensional view of a light source module 100′ according to another embodiment of the present invention. FIG. 2 and FIG. 3 illustrate different forms of recessed portions 112 and 112′, respectively, which may be formed by etching the circuit substrate 110. In FIG. 2, the recessed portion 112 includes a plurality of recessed spaces, and the light emitting units 120 are disposed one-to-one in the recessed spaces. The shape of the recessed space may be, but not limited to, rectangular, circular, polygonal, honeycomb, etc. In FIG. 3, the recessed portion 112′ is a strip type recessed space, and the light emitting units 120 are all disposed in the strip type recessed space. The strip type recessed space is exemplified as rectangular, but the present invention is not limited thereto. Furthermore, the circumference of the recessed portions 112, 112′ may also have chamfered or rounded edges.

Referring to FIG. 4, a cross-sectional view of the light source module 100 along the cutting line 4-4′ in FIG. 2 is shown. The circuit substrate 110 includes a first surface 114. The recessed portion 112 is recessed inwardly from the first surface 14, thereby forming a bottom 116 and a sidewall 118. The sidewall 118 may be connected to the bottom 116 in a tilted manner, but the present invention is not limited thereto. The light emitting units 120 are disposed on the bottom 116, and the light emitting units 120 are accommodated in the recessed portion 112 without extending beyond the first surface 114 of the circuit substrate 110, so that the light emitting units 120 are below the first surface 114 of the circuit substrate 110.

At least one of the bottom 116 and sidewall 118 may include a rough structure through surface treatment. Whether to provide the rough structure and the manner to arrange the rough structure depend on the user's design requirements. For example, the bottom 116 and the sidewall 118 may both have a rough structure through surface treatment to further diffuse the light emitted by the light emitting units 120.

Furthermore, the rough structure through surface treatment may also be compatible with other structures. For example, as shown in FIG. 5, a cross-sectional view of a light source module 200 according to still another embodiment of the present invention is shown. The light source module 200 may further include a reflective layer 140 to avoid loss of light. The reflective layer 140 may be disposed on at least one of the bottom 116 and the sidewall 118. Herein, the reflective layer 140 covers both the bottom 116 and the sidewall 118. But in other embodiments, the reflective layer 140 may be disposed on either the bottom 116 or the sidewall 118 in conjunction with the rough structure through surface treatment as mentioned above, so as to achieve different light diffusion effects.

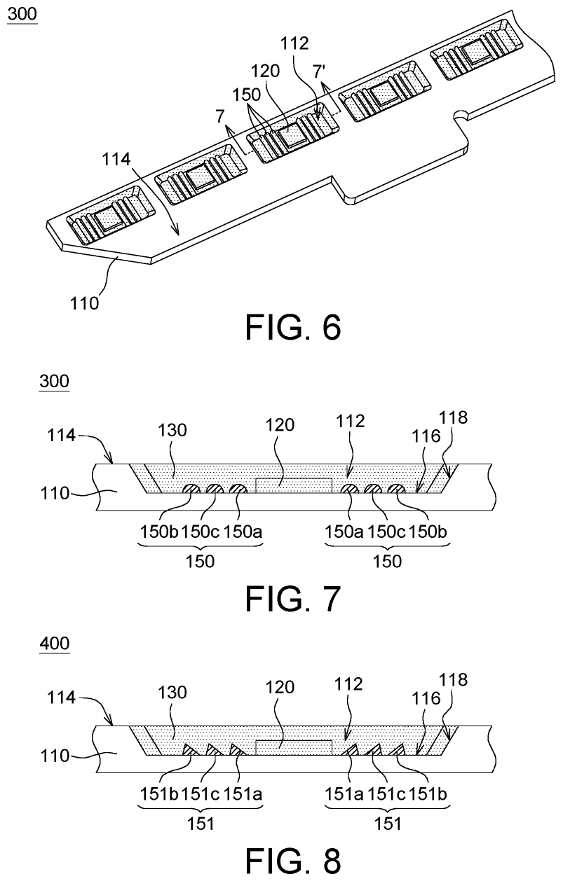

FIG. 6 is a three-dimensional view of a light source module 300 according to a further embodiment of the present invention. FIG. 7 is a cross-sectional view of the light source module 300 along the cutting line 7-7′ in FIG. 6. Referring to FIG. 6 and FIG. 7, the light source module 300 may further include a plurality of microstructures 150 to further increase the directivity of the light, or to further diffuse the light. The microstructures 150 may be disposed on at least one of the bottom 116 and the sidewall 118. Herein, the microstructures 150 are disposed on the bottom 116.

As shown in the embodiment of FIG. 6 and FIG. 7, each microstructure 150 is formed of a cylinder, and multiple cylinders are arranged parallel to each other on the bottom 116, but the microstructures 150 may also be arranged on the sidewall 118 at the same time or only on the sidewall 118.

In another embodiment, each microstructure may also include other shape. For example, referring to FIG. 8, a cross-sectional view of a light source module 400 according to other embodiment of the present invention is shown. The light source module 400 includes a plurality of microstructures 151 disposed on the bottom 116. Each microstructure 151 is formed of a triangular column, and the multiple triangular columns are arranged parallel to each other on the bottom 116, but the microstructures 151 may also be arranged on the sidewall 118 at the same time or only on the sidewall 118.

Of course, the microstructure is not limited to the shapes listed above, but may also include other shapes, which may be cones, spherical bumps, polygons, and a combination thereof. For example, in other embodiments not shown, the shape may be a combination of a cylinder as the microstructure 150 and a triangular column as the microstructure 151.

In addition, the material of the microstructures may be the same as the material of the circuit substrate 110. For example, they may be formed by etching the circuit substrate 110.

Referring to FIG. 7 and FIG. 8, in another embodiment, among these microstructures 150, 151 disposed on the bottom 116, the microstructure farther away from each of the light emitting units 120 has a higher height than the others. As shown in FIG. 7, the microstructure 150b is the farthest one distant from the light emitting unit 120. Therefore, the heights of the microstructures 150a, 150c and 150b may be increased sequentially so that the microstructures 150c and 150b, which are farther away from the light-emitting unit 120, have a higher chance of reflecting light. Similarly, as shown in FIG. 8, the microstructure 151b is the farthest one distant from the light emitting unit 120. Therefore, the heights of the microstructures 151a, 151c and 151b may be increased sequentially so that the microstructures 151c and 151b, which are farther away from the light emitting unit 120, have a higher chance of reflecting light.

It is worth mentioning that the rough structure through surface treatment and the reflective layer as mentioned above may also be in conjunction with the microstructure to be disposed on at least one of the bottom 116 and the sidewall 118. The user may change the above design depending on the desired product requirements to achieve various required effects, such as the effect of diffusing light, increasing light directivity by focusing light in a certain direction, or increasing the light dispersion angle.

Furthermore, the light source module may further include a secondary optical lens (not illustrated) covering the recessed portion 112, and the wavelength converting layer 130 further fills the secondary optical lens and is located between the bottom 116 and the secondary optical lens. The secondary optical lens is, for example, a convex lens, a concave lens, or a combination thereof, wherein the convex lens and the concave lens may be a spherical lens, an aspheric lens, or a free-form lens. In one embodiment, if the recessed portion 112 forms a plurality of recessed spaces as shown in FIG. 2, correspondingly the number of secondary optical lenses is also plural and covers each recessed space in a one-to-one manner. In another example, if the recessed portion 112′ forms a strip type recessed space as shown in FIG. 3, the secondary optical lens covers the strip type recessed space completely. The user may select different shapes of the secondary optical lens to effectively change the direction of the light, for example, to diffuse the light, to focus the light in a certain direction to improve the light directivity, or to improve the light dispersion angle to meet the product application requirements.

Although the light source modules mentioned above are examples for the application of a backlight module of a display device, the present invention is not limited thereto. In other embodiments, the light source module may also be an illumination device, or other device for providing a light source.

The above-mentioned design provides a recessed portion in the circuit substrate, which not only extends the light mixing distance, but also further reduces the thickness of the light source module under the condition of maintaining a certain light mixing distance, which is beneficial to the trend of narrow bezel nowadays. Moreover, the recessed portion of the circuit substrate reduces the thickness of the circuit substrate, thus reducing the distance between the light emitting unit and the heat dissipation element, reducing the thermal impedance, and improving the heat dissipation effect of the light emitting unit. In addition, the recessed portion may be provided with a special structure, such as a rough structure formed through surface treatment, a reflective layer and/or a plurality of microstructure, so that the light emitted from the light emitting unit may be mixed and transmitted adequately in the recessed portion. Furthermore, a secondary optical lens may be disposed above the recessed portion to change the direction of the light according to the application requirements of the product.

It will be apparent to those skilled in the art that various modifications and variations can be made to the disclosed embodiments. It is intended that the specification and examples be considered as exemplary only, with a true scope of the invention being indicated by the following claims and their equivalents.

What is claimed is:

1. A light source module comprising:
a circuit substrate comprising a first surface and having a recessed portion recessed inwardly from the first surface, and the circuit substrate forming a bottom and a sidewall in the recessed portion;
a plurality of light emitting units disposed on the bottom and located in the recessed portion;
a plurality of microstructures disposed on at least one of the bottom and the sidewall; and
a wavelength converting layer covering the light emitting units and filling the recessed portion.

2. The light source module according to claim 1, wherein the recessed portion comprises a plurality of recessed spaces, and the light emitting units are disposed one-to-one in the recessed spaces.

3. The light source module according to claim 1, wherein the recessed portion is a strip type recessed space, and the light emitting units are all disposed in the strip type recessed space.

4. The light source module according to claim 1, wherein the sidewall is connected to the bottom in a tilted manner.

5. The light source module according to claim 1, further comprising a reflective layer disposed on at least one of the bottom and the sidewall.

6. The light source module according to claim 1, wherein at least one of the bottom and the sidewall comprises a rough structure through surface treatment.

7. The light source module according to claim 1, wherein among the microstructures disposed on the bottom, the microstructure farther away from each of the light emitting units has a higher height than the others.

8. The light source module according to claim 1, further comprising a secondary optical lens covering the recessed portion, wherein the wavelength converting layer is located between the bottom and the secondary optical lens.

9. The light source module according to claim 1, wherein the light emitting units are below the first surface of the circuit substrate.
